(19) United States
(12) Patent Application Publication
(10) Pub. No.: US 2026/0255638 A1
(43) Pub. Date: Aug. 27, 2026

(54) SILICON CARBIDE SEMICONDUCTOR DEVICE

(71) Applicant: SUMITOMO ELECTRIC INDUSTRIES, LTD., Osaka (JP)

(72) Inventor: Kosuke UCHIDA, Osaka (JP)

(21) Appl. No.: 18/853,226

(22) PCT Filed: Jan. 25, 2023
(86) PCT No.: PCT/JP2023/002283

§ 371 Date: Oct. 1, 2024

(30) Foreign Application Priority Data
May 25, 2022 (JP) 2022-085313

(51) Int. Cl. H10D 62/10; H10D 30/01; H10D 30/66; H10D 62/00; H10D 62/832

(52) U.S. Cl. CPC H10D 62/109; H10D 30/0297; H10D 30/668; H10D 62/054; H10D 62/8325

(57) ABSTRACT

A silicon carbide semiconductor device includes a silicon carbide substrate having first and second main surfaces and including a drift region and an electric field relaxation region. The drift region includes a first region between the electric field relaxation region and the first main surface, a second region adjacent to the first region, a third region between the second region and the second main surface, and a fourth region between the electric field relaxation region and the third region; and the second main surface. A first maximum value of an effective concentration in the first region is greater than a second maximum value of an effective concentration in the second region, a third maximum value of an effective concentration in the third region is the second maximum value or less, and a fourth maximum value of an effective concentration in the fourth region is the third maximum value or less.

### TECHNICAL FIELD

The present disclosure relates to a silicon carbide semiconductor device.

This application is based on and claims priority to Japanese Patent Application No. 2022-085313 filed on May 25, 2022, the entire contents of which are incorporated herein by reference.

### BACKGROUND

A silicon carbide semiconductor device is disclosed in which a current diffusion region that is in contact with a lower surface of a gate trench is provided, and an electric field relaxation region that is in contact with a lower surface of the current diffusion region is provided wider than the current diffusion region.

### RELATED ART DOCUMENT

### Patent Document

[Patent Document 1] WO 2014/115253

[Patent Document 2] Japanese Laid-open Patent Application Publication No. 2017-50516

### SUMMARY OF THE INVENTION

### Problem to be Solved by the Invention

A silicon carbide semiconductor device according to the present disclosure includes a silicon carbide substrate having a first main surface and a second main surface opposite to the first main surface. The silicon carbide substrate includes a drift region being of a first conductivity type, a body region provided on the drift region, the body region being of a second conductivity type different from the first conductivity type, and a source region provided on the body region so as to be separated from the drift region, the source region being of the first conductivity type. A gate trench defined by a side surface and a bottom surface is provided in the first main surface, the side surface penetrating the source region and the body region to reach the drift region, and the bottom surface being continuous with the side surface. The silicon carbide substrate further includes an electric field relaxation region provided between the gate trench and the second main surface, the electric field relaxation region being of the second conductivity type. The drift region includes a first region located between the electric field relaxation region and the first main surface, a second region adjacent to the first region in a plane parallel to the first main surface, a third region located between the second region and the second main surface, connected to the second region, and adjacent to the electric field relaxation region in a plane parallel to the first main surface, and a fourth region located between the electric field relaxation region and the third region; and the second main surface, and connected to the third region. A first maximum value of an effective concentration of an impurity of the first conductivity type in the first region is greater than a second maximum value of an effective concentration of the impurity of the first conductivity type in the second region, a third maximum value of an effective concentration of the impurity of the first conductivity type in the third region is less than or equal to the second maximum value, and a fourth maximum value of an effective concentration of the impurity of the first conductivity type in the fourth region is less than or equal to the third maximum value.

### BRIEF DESCRIPTION OF THE DRAWINGS

FIG. 1 is a cross-sectional view illustrating a configuration of a silicon carbide semiconductor device according to a first embodiment.

FIG. 2 is a graph indicating an example of the distribution of the effective concentration of an impurity.

FIG. 3 is a cross-sectional view (1) illustrating a method of manufacturing the silicon carbide semiconductor device according to the first embodiment.

FIG. 4 is a cross-sectional view (2) illustrating the method of manufacturing the silicon carbide semiconductor device according to the first embodiment.

FIG. 5 is a cross-sectional view (3) illustrating the method of manufacturing the silicon carbide semiconductor device according to the first embodiment.

FIG. 6 is a cross-sectional view (4) illustrating the method of manufacturing the silicon carbide semiconductor device according to the first embodiment.

FIG. 7 is a cross-sectional view (5) illustrating the method of manufacturing the silicon carbide semiconductor device according to the first embodiment.

FIG. 8 is a cross-sectional view (6) illustrating the method of manufacturing the silicon carbide semiconductor device according to the first embodiment.

FIG. 9 is a cross-sectional view (7) illustrating the method of manufacturing the silicon carbide semiconductor device according to the first embodiment.

FIG. 10 is a cross-sectional view (8) illustrating the method of manufacturing the silicon carbide semiconductor device according to the first embodiment.

FIG. 11 is a cross-sectional view (9) illustrating the method of manufacturing the silicon carbide semiconductor device according to the first embodiment.

FIG. 12 is a cross-sectional view illustrating a silicon carbide semiconductor device according to a second embodiment.

FIG. 13 is a cross-sectional view illustrating a method of manufacturing the silicon carbide semiconductor device according to the second embodiment.

FIG. 14 is a cross-sectional view illustrating a silicon carbide semiconductor device according to a third embodiment.

FIG. 15 is a cross-sectional view (1) illustrating a method of manufacturing the silicon carbide semiconductor device according to the third embodiment.

FIG. 16 is a cross-sectional view (2) illustrating the method of manufacturing the silicon carbide semiconductor device according to the third embodiment.

### DESCRIPTION OF THE EMBODIMENTS

### Problem to be Solved by the Present Disclosure

A conventional silicon carbide semiconductor device cannot achieve both the reduction in the on-resistance and the improvement in the breakdown voltage.

The present disclosure aims to provide a silicon carbide semiconductor device that can achieve both the reduction in the on-resistance and the improvement in the breakdown voltage.

### Effects of the Present Disclosure

According to the present disclosure, both the reduction in the on-resistance and the improvement in the breakdown voltage can be achieved.

Embodiments will be described below.

### Description of Embodiments of the Present Disclosure

First, embodiments of the present disclosure will be listed and described. In the following description, the same or corresponding elements are denoted by the same reference symbols, and the same description thereof will not be repeated. In the crystallographic description in the present specification, an individual orientation is represented by [ ], a group orientation is represented by < >, an individual plane is represented by ( ), and a group plane is represented by { }. Additionally, a negative crystallographic index is usually represented by placing a “-” (bar) on the top of a number, but in the present disclosure, a negative sign is placed before a number. Additionally, in the following description, an XYZ orthogonal coordinate system is used, but the coordinate system is defined for description and does not limit the posture of the silicon carbide semiconductor device or the like. Additionally, an XY plane view is referred to as a plan view, and when viewed from an arbitrary point, a +Z direction may be referred to as above, an upper side, or up, and a −Z direction may be referred to as below, a lower side, or down.
[1] A silicon carbide semiconductor device according to one aspect of the present disclosure includes a silicon carbide substrate having a first main surface and a second main surface opposite to the first main surface. The silicon carbide substrate includes a drift region being of a first conductivity type; a body region provided on the drift region, the body region being of a second conductivity type different from the first conductivity type; and a source region provided on the body region so as to be separated from the drift region, the source region being of the first conductivity type. A gate trench defined by a side surface and a bottom surface is provided in the first main surface, the side surface penetrating the source region and the body region to reach the drift region, and the bottom surface being continuous with the side surface. The silicon carbide substrate further includes an electric field relaxation region provided between the gate trench and the second main surface, the electric field relaxation region being of the second conductivity type. The drift region includes a first region located between the electric field relaxation region and the first main surface; a second region adjacent to the first region in a plane parallel to the first main surface; a third region located between the second region and the second main surface, connected to the second region, and adjacent to the electric field relaxation region in a plane parallel to the first main surface; and a fourth region located between the electric field relaxation region and the third region; and the second main surface, and connected to the third region. A first maximum value of an effective concentration of an impurity of the first conductivity type in the first region is greater than a second maximum value of an effective concentration of the impurity of the first conductivity type in the second region. A third maximum value of an effective concentration of the impurity of the first conductivity type in the third region is less than or equal to the second maximum value. A fourth maximum value of an effective concentration of the impurity of the first conductivity type in the fourth region is less than or equal to the third maximum value.

The first maximum value of the effective concentration of the impurity of the first conductivity type in the first region is greater than the second maximum value of the effective concentration of the impurity of the first conductivity type in the second region. Therefore, while reducing the on-resistance, excessive electric field concentration below the body region is suppressed, and a high breakdown voltage is obtained. Additionally, the third maximum value of the effective concentration of the impurity of the first conductivity type in the third region is less than or equal to the second maximum value and the fourth maximum value of the effective concentration of the impurity of the first conductivity type in the fourth region is less than or equal to the third maximum value, thereby suppressing an increase in the electrical resistance in the second region and the third region. As described, the reduction of the on-resistance and the improvement of the breakdown voltage can be achieved.
[2] In [1], the third maximum value may be greater than the fourth maximum value and less than the second maximum value. In this case, an excessive increase in the electrical resistance in the second region and the third region is easily suppressed.
[3] In [1] or [2], the electric field relaxation region may have a first surface that is in contact with the first region; a second surface opposite to the first surface. An effective concentration of an impurity of the second conductivity type in the electric field relaxation region may gradually decrease from a first virtual plane toward the second surface, the first virtual plane being apart from the first surface by 0.3 μm toward the second surface. In this case, electric field concentration on a gate insulating film at the bottom of the gate trench is easily relaxed.
[4] In any one of [1] to [3], the first maximum value may be 50% or greater of a fifth maximum value of an effective concentration of an impurity of the second conductivity type in the electric field relaxation region. In this case, the on-resistance is easily reduced.
[5] In any one of [1] to [4], the second maximum value may be 20% or greater of a fifth maximum value of an effective concentration of an impurity of the second conductivity type in the electric field relaxation region. In this case, at the time of avalanche breakdown, the electric field in the body region tends to be higher than the electric field in the electric field relaxation region on the second region. Positions where electric field concentration occurs are distributed, and a higher breakdown voltage is obtained.
[6] In any one of [1] to [5], a thickness of the electric field relaxation region may be 1 μm or greater. The electric field relaxation region may have a first surface that is in contact with the first region. The third region may have a third surface that is in contact with the second region and is flush with the first surface; and a fifth region between the third surface and a second virtual plane apart from the third surface by 1 μm toward the second main surface. An effective concentration of the impurity of the first conductivity type in the fifth region at a position apart from the third surface by a first distance toward the second main surface is 10% or greater of an effective concentration of an impurity of the second conductivity type in the electric field relaxation region at a position apart from the first surface by the first distance toward the second main surface. In this case, depletion in the electric field relaxation region is easily promoted, and electric field concentration easily occurs in the body region on the second region. Therefore, a higher breakdown voltage is easily obtained.
[7] In any one of [1] to [6], the bottom surface of the gate trench may be formed by the first region. In this case, the on-resistance is easily reduced.
[8] In any one of [1] to [7], a width of the first region may be greater than a width of the electric field relaxation region. In this case, the on-resistance is easily reduced.
[9] In any one of [1] to [8], the side surface of the gate trench may include a {0-33-8} plane. The side surface includes the {0-33-8} plane, so that favorable mobility can be obtained at the side surface of the gate trench, thereby reducing the channel resistance.

### First Embodiment

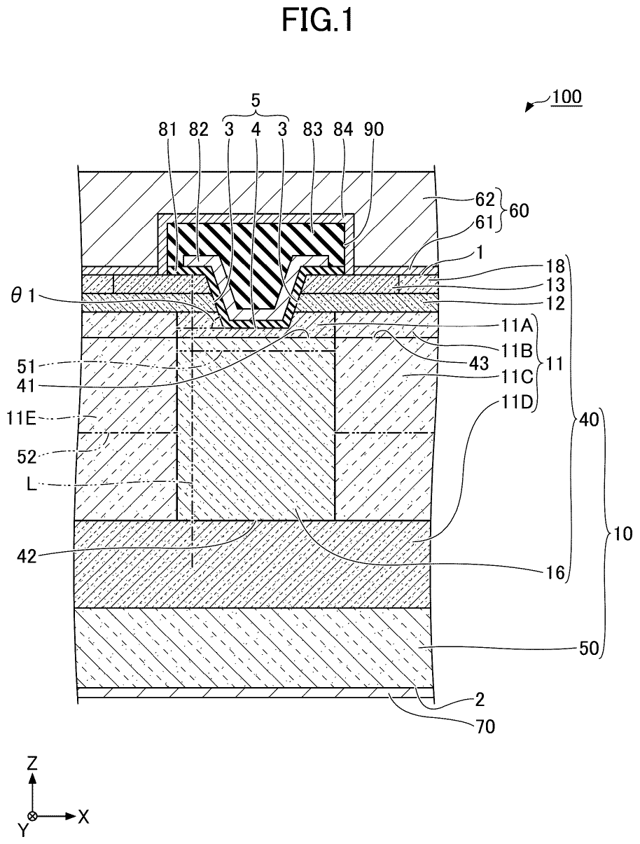

A first embodiment will be described. The first embodiment relates to what is called a vertical MOS field effect transistor (FET) using silicon carbide, and such an MOS FET is an example of a silicon carbide semiconductor device. FIG. 1 is a cross-sectional view illustrating a configuration of a silicon carbide semiconductor device according to the first embodiment.

As illustrated in FIG. 1, a silicon carbide semiconductor device 100 according to the first embodiment mainly includes a silicon carbide substrate 10, a gate insulating film 81, a gate electrode 82, an interlayer insulating film 83, a source electrode 60, and a drain electrode 70.

The silicon carbide substrate 10 has a first main surface 1 and a second main surface 2 opposite to the first main surface 1. The first main surface 1 and the second main surface 2 are parallel to the XY plane, and the first main surface 1 is in the +Z direction when viewed from the second main surface 2. The silicon carbide substrate 10 includes a silicon carbide single-crystal substrate 50 and a silicon carbide epitaxial layer 40 on the silicon carbide single-crystal substrate 50. The silicon carbide epitaxial layer 40 forms the first main surface 1, and the silicon carbide single-crystal substrate 50 forms the second main surface 2. The silicon carbide single-crystal substrate 50 and the silicon carbide epitaxial layer 40 are made of, for example, hexagonal silicon carbide of polytype 4H. The silicon carbide single-crystal substrate 50 contains an n-type impurity such as nitrogen (N), for example, and is of an n-type conductivity type (a first conductivity type).

The first main surface 1 is a {0001} plane or a plane inclined from the {0001} plane by an off angle of 8° or less in the off direction. Preferably, the first main surface 1 is a (000-1) plane or a plane inclined from the (000-1) plane by an off angle of 8° or less in the off direction. The off direction may be, for example, a <11-20> direction or a <1-100> direction. The off angle may be, for example, 1° or greater, or 2 or greater. The off angle may be 6° or less or 4° or less.

The silicon carbide epitaxial layer 40 mainly includes a drift region 11, a body region 12, a source region 13, a contact region 18, and an electric field relaxation region 16.

The drift region 11 contains an n-type impurity, such as nitrogen or phosphorus (P), for example, and is of the n-type conductivity type.

The drift region 11 includes a first region 11A, a second region 11B, a third region 11C, and a fourth region 11D.

The fourth region 11D is provided on the silicon carbide single-crystal substrate 50. The lower surface of the fourth region 11D and the upper surface of the silicon carbide single-crystal substrate 50 are in contact with each other. The effective concentration of the n-type impurity in the fourth region 11D is, for example, 1.0×10¹⁵ cm⁻³ or greater and 5.0×10¹⁶ cm⁻³.

The electric field relaxation region 16 contains a p-type impurity, such as aluminum (Al), for example, and is of a p-type conductivity type (a second conductivity type). The electric field relaxation region 16 is provided on a portion of the fourth region 11D. The lower surface of the electric field relaxation region 16 and the upper surface of the fourth region 11D are in contact with each other. The effective concentration of the p-type impurity in the electric field relaxation region 16 is, for example, 1.0×10¹⁶ cm⁻³ or greater and 5.0×10¹⁸ cm⁻³ or less. The lower surface of the electric field relaxation region 16 may be separated from the upper surface of the fourth region 11D, and a portion of the third region 11C may be present therebetween. Additionally, the lower surface of the electric field relaxation region 16 and the lower surface of the third region 11C may be non-flush with each other, and the lower surface of the electric field relaxation region 16 may be closer to the second main surface 2 than the lower surface of the third region 11C is. That is, the electric field relaxation region 16 may be formed deeper than the third region 11C.

The third region 11C is provided on a portion of the fourth region 11D. The lower surface of the third region 11C and the upper surface of the fourth region 11D are in contact with each other. The third region 11C is adjacent to the electric field relaxation region 16. The side surface of the third region 11C and the side surface of the electric field relaxation region 16 are in contact with each other. The effective concentration of the n-type impurity in the third region 11C is, for example, 5.0×10¹⁵ cm⁻³ or greater and 2.0×10¹⁸ cm⁻³ or less.

The first region 11A is provided on the electric field relaxation region 16. The lower surface of the first region 11A and the upper surface of the electric field relaxation region 16 are in contact with each other. The effective concentration of the n-type impurity in the first region 11A is, for example, 1.0×10¹⁶ cm⁻³ and 2.0×10¹⁸ cm⁻³ or less.

The second region 11B is provided on the third region 11C. The lower surface of the second region 11B and the upper surface of the third region 11C are in contact with each other. The second region 11B is adjacent to the first region 11A. The side surface of the second region 11B and the side surface of the first region 11A are in contact with each other. The effective concentration of the n-type impurity in the second region 11B is, for example, 1.0×10¹⁶ cm^{31 3} or greater and 1.0×10¹⁸ cm⁻³ or less. The first region 11A and the second region 11B may be referred to as a current diffusion region.

For example, the interface between the third region 11C and the second region 11B is flush with the interface between the electric field relaxation region 16 and the first region 11A. The interface between the third region 11C and the second region 11B may be closer to the first main surface 1 or the second main surface 2 than the interface between the electric field relaxation region 16 and the first region 11A is. The interface between the first region 11A and the second region 11B may be flush with the interface between the electric field relaxation region 16 and the third region 11C, or may be over the third region 11C. That is, the width of the first region 11A may be equal to the width of the electric field relaxation region 16 or may be greater than the width of the electric field relaxation region 16.

As described, the first region 11A is located between the electric field relaxation region 16 and the first main surface 1. The second region 11B is adjacent to the first region 11A in a plane parallel to the first main surface 1. The third region 11C is located between the second region 11B and the second main surface 2, is connected to the second region 11B, and is adjacent to the electric field relaxation region 16 in a plane parallel to first main surface 1. The fourth region 11D is located between the electric field relaxation region 16 and the third region 11C; and the second main surface 2, and is connected to the third region 11c.

The body region 12 contains a p-type impurity such, as aluminum, for example, and is of the p-type conductivity type. The body region 12 is provided on the drift region 11. The body region 12 is provided on the first region 11A and the second region 11B. The effective concentration of the p-type impurity in the body region 12 is, for example, 1.0×10¹⁷ cm⁻³ or greater and 5.0×10¹⁸ cm⁻³ or less.

The source region 13 contains an n-type impurity, such as nitrogen or phosphorus, for example, and is of the n-type conductivity type.

The source region 13 is provided on the body region 12. The source region 13 is separated from the drift region 11 by the body region 12. The source region 13 forms the first main surface 1. The effective concentration of the n-type impurity in the source region 13 is, for example, 5.0×10¹⁸ cm⁻³ or greater and 2.0×10²⁰ cm⁻³ or less.

The contact region 18 contains a p-type impurity, such as aluminum, for example, and is of the p-type conductivity type. The contact region 18 penetrates the source region 13 and is in contact with the body region 12. The contact region 18 forms the first main surface 1. The effective concentration of the p-type impurity concentration of the contact region 18 is, for example, 1.0×10¹⁸ cm⁻³ or greater and 5.0×10²⁰ cm⁻³ or less. The electric field relaxation region 16 is electrically connected to the contact region 18. Here, the contact region 18 may be formed at a position appearing in a cross section different from the cross section illustrated in FIG. 1.

A gate trench 5 defined by side surfaces 3 and a bottom surface 4 is provided in the first main surface 1. The gate trench 5 extends along, for example, the Y-axis. The side surfaces 3 penetrate the source region 13, the body region 12, and a portion of the first region 11A, and reaches the first region 11A. The bottom surface 4 is continuous with the side surfaces 3. The bottom surface 4 is located in the first region 11A. For example, the bottom surface 4 is parallel to the first main surface 1 and the second main surface 2. The angle θ1 of the side surface 3 with respect to a plane including the bottom surface 4 is, for example, 45° or greater and 65 or less. The angle θ1 may be, for example, 50° or greater. The angle θ1 may be, for example, 60° or less. The side surface 3 preferably has a {0-33-8} plane. The {0-33-8} plane is a crystal plane that provides excellent mobility.

The gate insulating film 81 is, for example, an oxide film. The gate insulating film 81 is made of, for example, a material containing silicon dioxide. The gate insulating film 81 is in contact with the side surfaces 3 and the bottom surface 4. The gate insulating film 81 is in contact with the first region 11A at the bottom surface 4. The gate insulating film 81 is in contact with the source region 13, the body region 12, and the first region 11A at the side surfaces 3. The gate insulating film 81 may be in contact with the source region 13 at the first main surface 1.

The gate electrode 82 is provided on the gate insulating film 81. The gate electrode 82 is made of, for example, polysilicon (poly-Si) containing a conductive impurity. The gate electrode 82 is disposed inside the gate trench 5. A portion of the gate electrode 82 may be disposed on the first main surface 1.

The interlayer insulating film 83 covers the gate electrode 82. The interlayer insulating film 83 is in contact with the gate electrode 82 and the gate insulating film 81. The interlayer insulating film 83 is, for example, an oxide film. The interlayer insulating film 83 is made of, for example, a material containing silicon dioxide. The interlayer insulating film 83 electrically insulates the gate electrode 82 and the source electrode 60 from each other. A portion of the interlayer insulating film 83 may be provided inside the gate trench 5.

A barrier metal film 84 is provided to cover the upper surface and the side surfaces of the interlayer insulating film 83 and the side surfaces of the gate insulating film 81. The barrier metal film 84 is in contact with the interlayer insulating film 83 and the gate insulating film 81. The barrier metal film 84 is made of, for example, a material containing titanium nitride (TiN).

A contact hole 90 is formed in the interlayer insulating film 83 and the gate insulating film 81. The source region 13 is exposed from the interlayer insulating film 83 and the gate insulating film 81 through the contact hole 90.

The source electrode 60 is in contact with the first main surface 1. The source electrode 60 includes a contact electrode 61 provided in the contact hole 90, and a source interconnect 62. The contact electrode 61 is in contact with the source region 13 and the contact region 18 at the first main surface 1. The contact electrode 61 is made of, for example, a material containing nickel silicide (NiSi). The contact electrode 61 may be made of a material containing titanium (Ti), aluminum, and silicon. The contact electrode 61 is in ohmic contact with the source region 13 and the contact region 18. The source interconnect 62 covers the upper surface and the side surfaces of the interlayer insulating film 83 and the upper surface of the contact electrode 61. The source interconnect 62 is in contact with the barrier metal film 84 and the contact electrode 61. The source interconnect 62 is made of, for example, a material containing aluminum. The potential is applied from the source electrode 60 to the body region 12 and the electric field relaxation region 16 via the contact region 18.

The drain electrode 70 is in contact with the second main surface 2. The drain electrode 70 is in contact with the silicon carbide single-crystal substrate 50 at the second main surface 2. The drain electrode 70 is electrically connected to the drift region 11. The drain electrode 70 is made of, for example, a material containing nickel silicide. The drain electrode 70 may be made of a material containing titanium, aluminum, and silicon. The drain electrode 70 is in ohmic contact with the silicon carbide single-crystal substrate 50.

A buffer layer containing an n-type impurity, such as nitride, and being of the n-type conductivity type may be provided between the silicon carbide single-crystal substrate 50 and the fourth region 11D. The effective concentration of the n-type impurity of the buffer layer may be higher than the effective concentration of the n-type impurity of the fourth region 11D.

The effective concentration of the p-type impurity in the p-type region is a value obtained by subtracting the concentration of the n-type impurity from the concentration of the p-type impurity in the region. The effective concentration of the n-type impurity in the n-type region is a value obtained by subtracting the concentration of the p-type impurity from the concentration of the n-type impurity in the region. The effective concentration of the p-type impurity and the effective concentration of the n-type impurity can be measured by, for example, a scanning capacitance microscope (SCM) method, a secondary ion mass spectrometry (SIMS) method, or the like. The position of the boundary surface between the p-type region and the n-type region (that is, the pn junction interface) can be identified by, for example, the SCM method, the SIMS method, or the like.

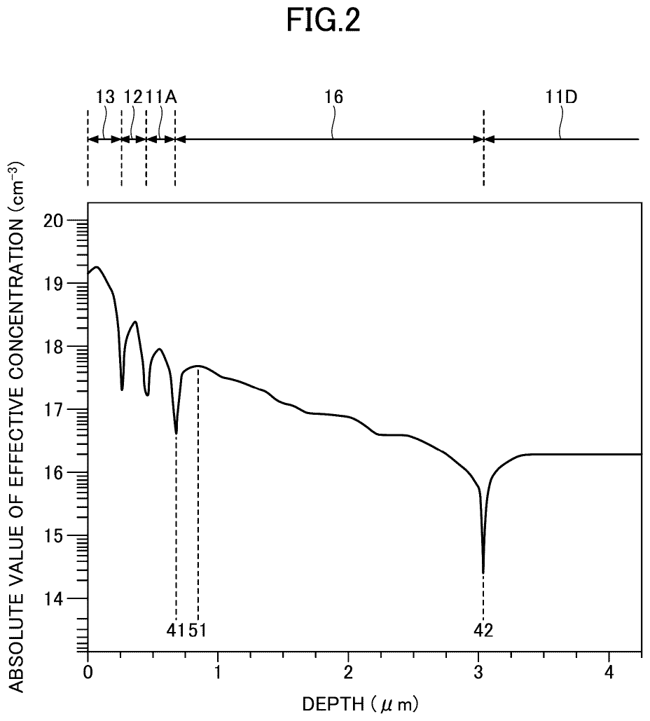

Next, a relationship of the effective concentration between the regions in the first embodiment will be described. FIG. 2 is a graph indicating an example of the distribution of the effective concentration of the impurity. FIG. 2 indicates the distribution of the absolute value of the effective concentration of the impurity along the dot-dot-dash line L in FIG. 1. The horizontal axis of FIG. 2 represents the depth with reference to the first main surface 1, and the vertical axis represents the absolute value of the effective concentration of the impurity.

In the embodiment, a first maximum value of the effective concentration of the n-type impurity in the first region 11A is greater than a second maximum value of the effective concentration of the n-type impurity in the second region 11B. A third maximum value of the effective concentration of the n-type impurity in the third region 11C is less than or equal to the second maximum value. A fourth maximum value of the effective concentration of the n-type impurity in the fourth region 11D is less than or equal to the third maximum value.

As illustrated in FIG. 2, the maximum value of the effective concentration of the n-type impurity in the source region 13 may be greater than the maximum value of the effective concentration of the p-type impurity in the body region 12. The maximum value of the effective concentration of the p-type impurity in the body region 12 may be greater than the first maximum value of the effective concentration of the n-type impurity in the first region 11A. The first maximum value of the effective concentration of the n-type impurity in the first region 11A may be greater than a fifth maximum value of the effective concentration of the p-type impurity in the electric field relaxation region 16.

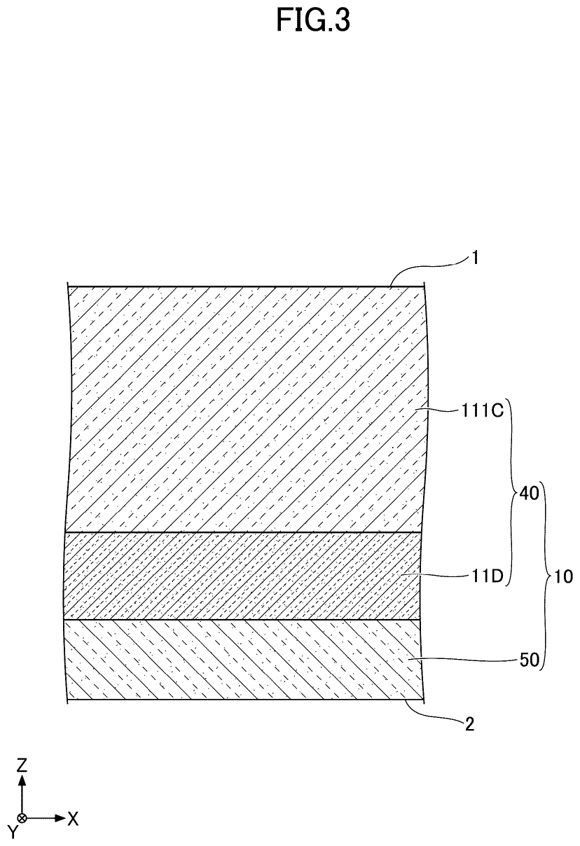

Next, a method of manufacturing the silicon carbide semiconductor device 100 according to the first embodiment will be described. FIG. 3 to FIG. 11 are cross-sectional views illustrating the method of manufacturing the silicon carbide semiconductor device according to the first embodiment.

First, as illustrated in FIG. 3, the silicon carbide single-crystal substrate 50 is prepared. Next, the silicon carbide epitaxial layer 40 is formed on the silicon carbide single-crystal substrate 50. The silicon carbide epitaxial layer 40 includes the fourth region 11D and an n-type region 1110 in which the third region 11C and the like are to be formed later. For example, the silicon carbide single-crystal substrate 50 contains an n-type impurity, such as nitrogen, and is of the n-type conductivity type. For example, the silicon carbide epitaxial layer 40 can be formed by epitaxial growth with an n-type impurity, such as nitrogen, being added. In such a way, the silicon carbide substrate 10 having the first main surface 1 and the second main surface 2 is obtained.

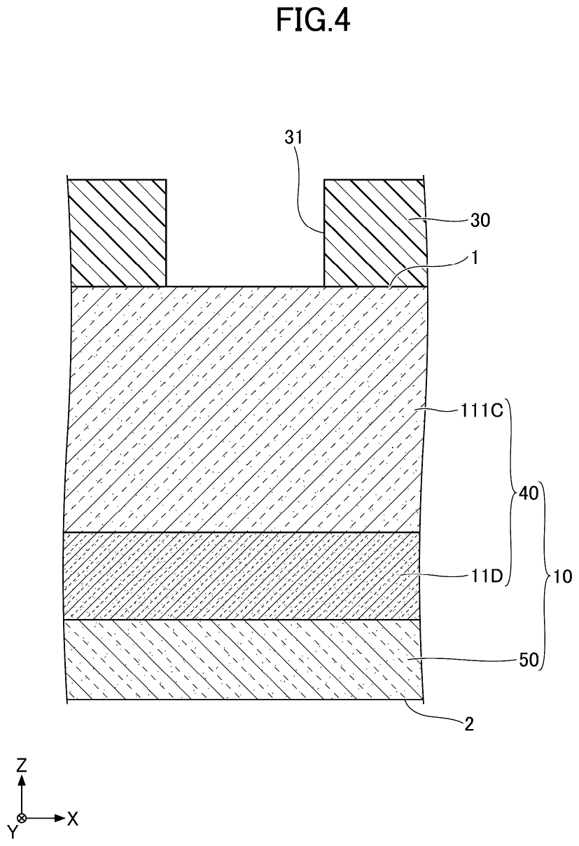

Next, as illustrated in FIG. 4, a resist mask 30 is formed on the silicon carbide epitaxial layer 40. In the resist mask 30, an opening 31 exposing a region, in which the electric field relaxation region 16 of the n-type region 1110 is to be formed, is formed.

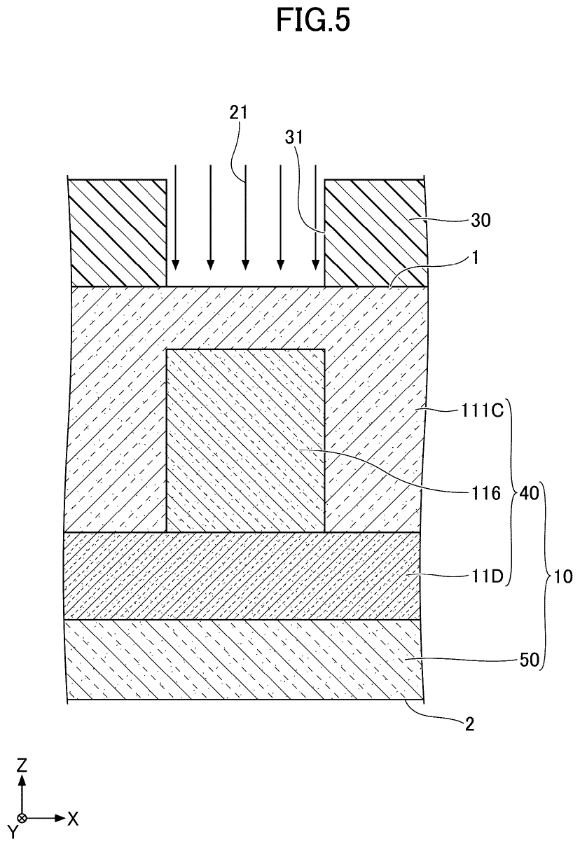

Next, as illustrated in FIG. 5, a p-type region 116 is formed in the n-type region 111C by performing ion implantation of a p-type impurity 21 through the opening 31. The p-type region 116 is a region to be the electric field relaxation region 16, and is formed to a region shallower than the electric field relaxation region 16. In the ion implantation of the p-type impurity 21, for example, channeling implantation is performed. That is, the ion implantation is performed perpendicular to the {0001} plane.

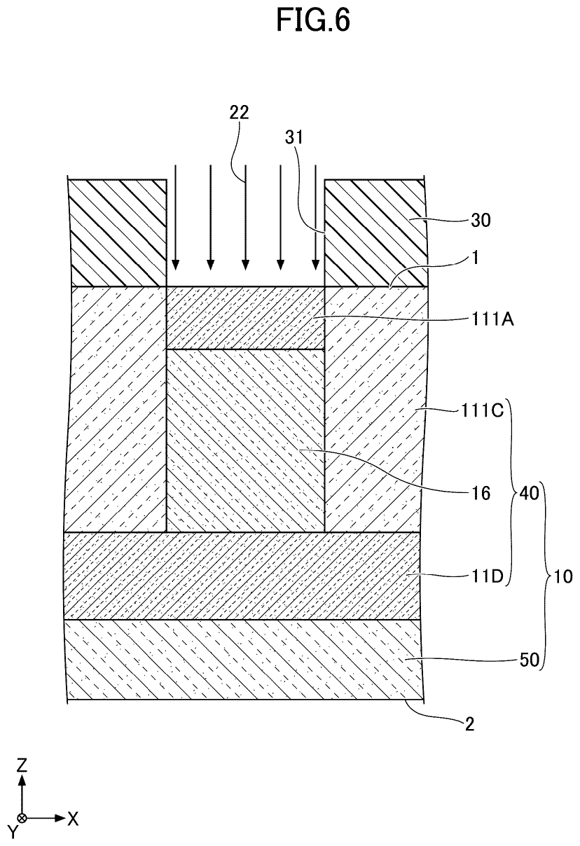

Next, as illustrated in FIG. 6, an n-type region 111A is formed in the n-type region 111C by performing ion implantation of an n-type impurity 22 through the opening 31. The n-type region 111A is a region to be the first region 11A, and is formed to a region shallower than the first region 11A. For example, the n-type region 111A forms the first main surface 1. Additionally, the n-type region 111A is formed so as to overlap with a portion of the p-type region 116. Along with the formation of the n-type region 111A, the electric field relaxation region 16 is formed from the p-type region 116. In the ion implantation of the n-type impurity 22, the ion implantation is performed along the Z-axis and perpendicular to the first main surface 1.

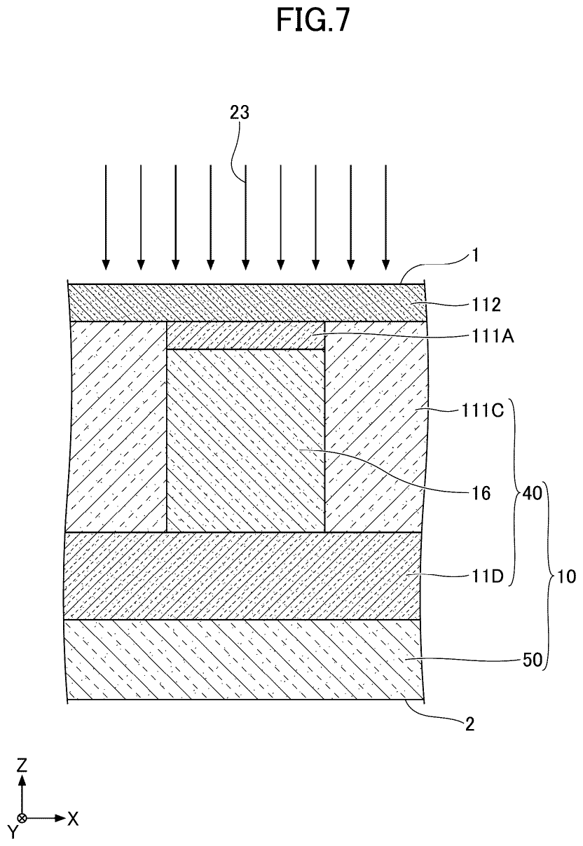

Next, as illustrated in FIG. 7, the resist mask 30 is removed, and ion implantation of a p-type impurity 23 is performed on the entire first main surface 1, thereby forming a p-type region 112 in the n-type regions 111C and 111A. The p-type region 112 is a region to be the body region 12, and is formed to a region shallower than the body region 12. For example, the p-type region 112 forms the first main surface 1. In the ion implantation of the p-type impurity 23, the ion implantation is performed along the Z-axis and perpendicular to the first main surface 1.

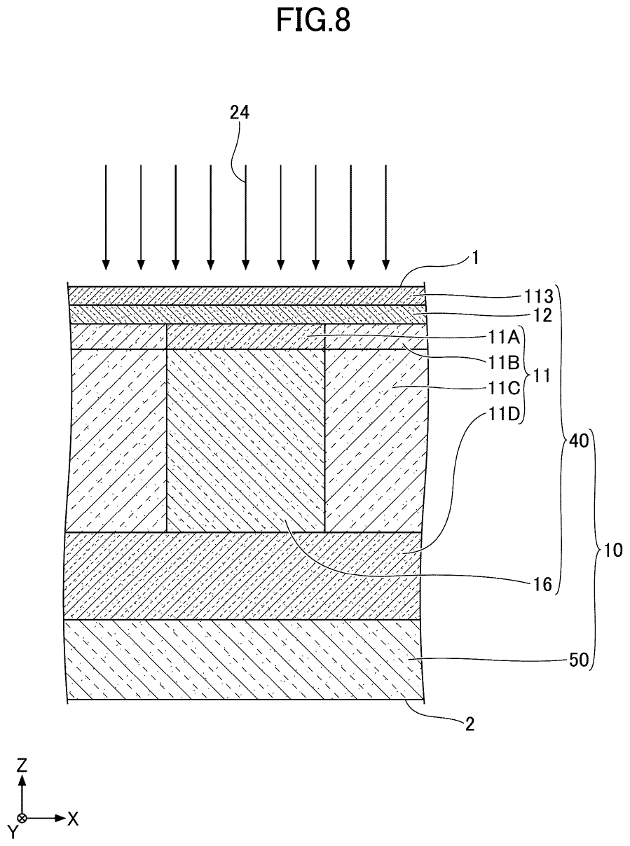

Next, as illustrated in FIG. 8, by performing ion implantation of an n-type impurity 24 on the entire first main surface 1, an n-type region 113 is formed in the p-type region 112, the first region 11A is formed in the n-type region 111A, and the second region 11B is formed in the n-type region 111C. Along with the formation of the second region 11B, the third region 11C is formed from the n-type region 111C. In the ion implantation of the n-type impurity 24, the ion implantation is performed along the Z-axis and perpendicular to the first main surface 1.

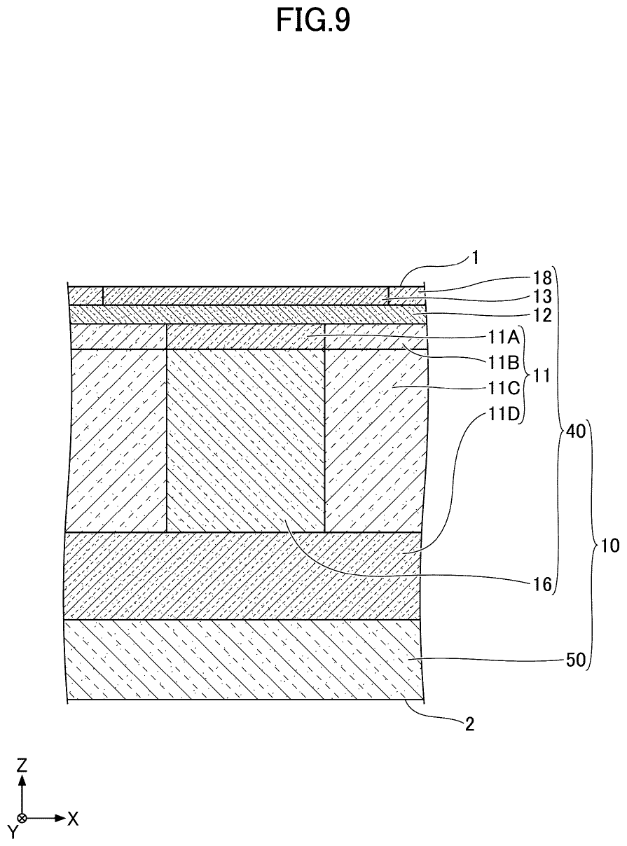

Next, as illustrated in FIG. 9, the contact region 18 is formed in the n-type region 113 by performing ion implantation of a p-type impurity on a portion of the first main surface 1 by using a resist mask (not illustrated). Along with the formation of the contact region 18, the source region 13 is formed from the n-type region 113. In the ion implantation of the p-type impurity, the ion implantation is performed along the Z-axis and perpendicular to the first main surface 1.

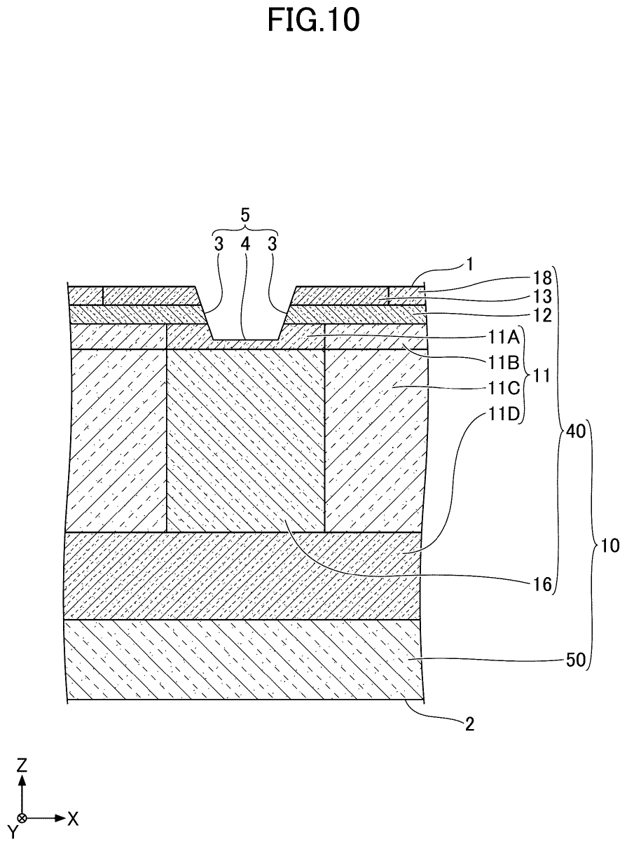

Next, as illustrated in FIG. 10, the gate trench 5 having the side surfaces 3 and the bottom surface 4 is formed. The gate trench 5 can be formed by, for example, reactive ion etching (RIE), thermal etching, or the like using a mask.

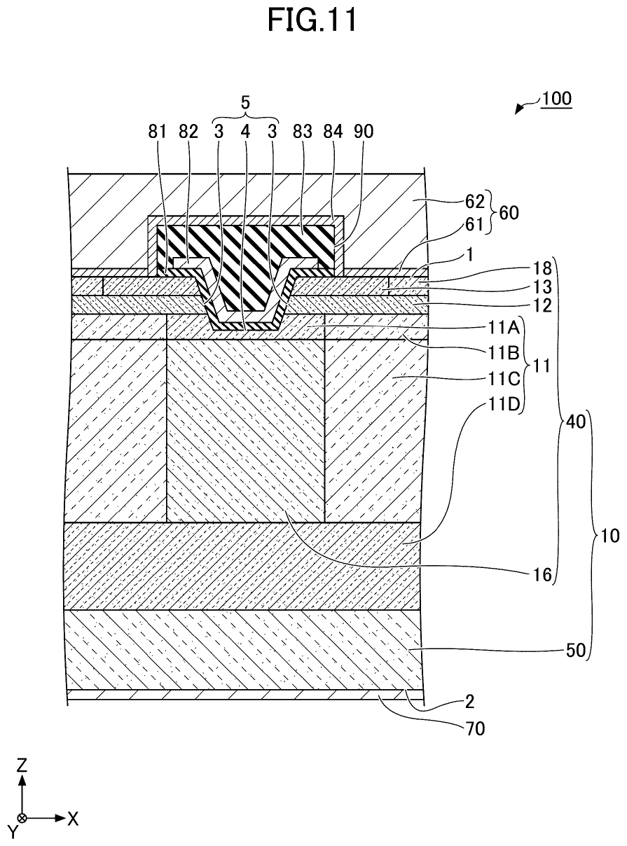

Next, as illustrated in FIG. 11, the gate insulating film 81, the gate electrode 82, and the interlayer insulating film 83 are formed. Next, the contact hole 90 is formed in the gate insulating film 81 and the interlayer insulating film 83, and the barrier metal film 84 is formed. Next, the source electrode 60 including the contact electrode 61 and the source interconnect 62 is formed. Additionally, the drain electrode 70 is formed.

In such a way, the silicon carbide semiconductor device 100 according to the first embodiment can be manufactured.

In the silicon carbide semiconductor device 100 according to the first embodiment, the first maximum value of the effective concentration of the n-type impurity in the first region 11A is greater than the second maximum value of the effective concentration of the n-type impurity in the second region 11B. Therefore, while reducing the on-resistance, excessive electric field concentration below the body region 12 is suppressed, and a high breakdown voltage is obtained. Additionally, the second maximum value is less than the first maximum value, and thus the capacitance between the source electrode 60 and the drain electrode 70 can be suppressed to be low, and switching loss can be reduced.

Additionally, the third maximum value of the effective concentration of the n-type impurity in the third region 11C is less than or equal to the second maximum value. Therefore, an increase in the electric resistance in the second region 11B can be suppressed. Preferably, the third maximum value is greater than the fourth maximum value.

Additionally, the fourth maximum value of the effective concentration of the n-type impurity in the fourth region 11D is less than or equal to the third maximum value. Therefore, an increase in the electric resistance in the third region 11C can be suppressed. For example, when the electric field relaxation regions 16 and the third regions 11C are alternately arranged and multiple cells are disposed, the electric resistance in the third region 11c between the adjacent electric field relaxation regions 16 can be suppressed to be low. Preferably, the third maximum value is less than the second maximum value.

The electric field relaxation region 16 has a first surface 41 that is in contact with the first region 11A and a second surface 42 opposite to the first surface 41. Preferably, as illustrated in FIG. 2, the effective concentration of the p-type impurity in the electric field relaxation region 16 gradually decreases from a first virtual plane 51, which is 0.3 μm apart from the first surface 41 toward the second surface 42, to the second surface 42. In this case, electric field concentration on the gate insulating film 81 at the bottom of the gate trench 5 is easily relaxed.

The first maximum value is preferably 50% or greater of the fifth maximum value of the effective concentration of the p-type impurity in the electric field relaxation region 16. In this case, the on-resistance is easily reduced. The first maximum value is more preferably 60% or greater, and still more preferably 70% or greater of the fifth maximum value. Here, in order to suppress punch-through in a portion of the body region 12 functioning as a channel, the first maximum value is preferably less than the maximum value of the effective concentration of the p-type impurity in the body region 12.

The second maximum value is preferably 20% or greater of the fifth maximum value of the effective concentration of the p-type impurity in the electric field relaxation region 16. In this case, at the time of avalanche breakdown, the electric field in the body region 12 on the second region 11B tends to be higher than the electric field in the electric field relaxation region 16.

Positions where electric field concentration occurs are distributed, and a higher breakdown voltage is obtained. The second maximum value is more preferably 30% or greater, and still more preferably 40% or greater of the fifth maximum value.

The third region 11C has a third surface 43 that is flush with the first surface 41. The third surface 43 is in contact with the second region 11B. The third region 11C further includes a fifth region 11E. The fifth region 11E is a region between the third surface 43 and a second virtual surface 52, which is 1 μm apart from the third surface 43 toward the second main surface 2. The thickness of the electric field relaxation region 16 is 1 μm or greater, and the effective concentration of the n-type impurity in the fifth region 11E at a position spaced apart from the third surface 43 by a first length toward the second main surface 2 is preferably 10% or greater, more preferably 20% or greater, and still more preferably 30% or greater of the effective concentration of the p-type impurity in the electric field relaxation region 16 at a position spaced apart from the first surface 41 by the first length toward the second main surface 2. When such a relationship is satisfied, depletion in the electric field relaxation region 16 is easily promoted. Additionally, electric field concentration is likely to occur in the body region 12 in the second region 11B. Therefore, a higher breakdown voltage can be obtained. The thickness of the electric field relaxation region 16 is preferably 1 μm or greater, more preferably 1.5 μm or greater, and still more preferably 2 μm or greater.

In the present embodiment, the bottom surface 4 of the gate trench 5 is formed by the first region 11A, so that the on-resistance is easily reduced. Additionally, when the width of the first region 11A is greater than the width of the electric field relaxation region 16, the on-resistance is more easily reduced.

### Second Embodiment

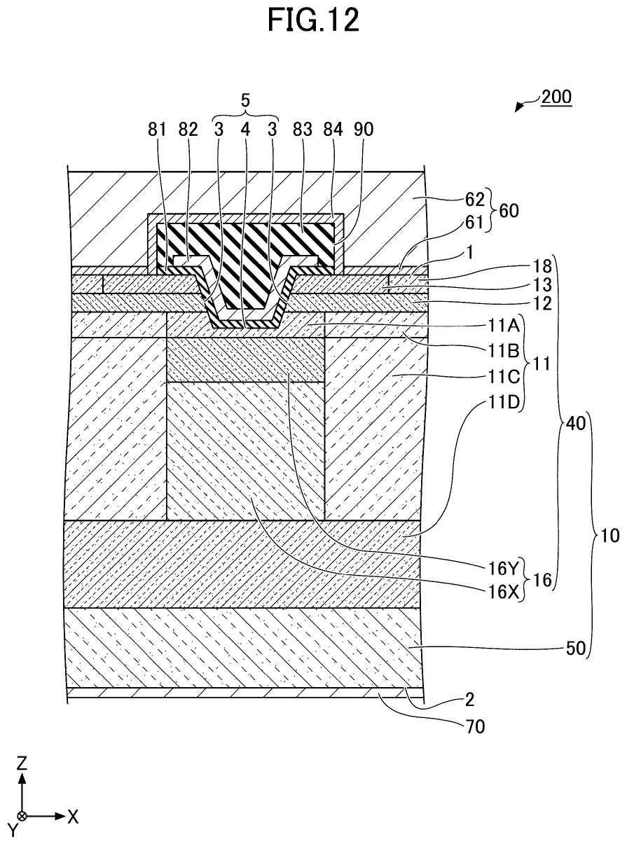

A second embodiment will be described. The second embodiment is different from the first embodiment mainly in the configuration of the electric field relaxation region 16. FIG. 12 is a cross-sectional view illustrating a silicon carbide semiconductor device according to the second embodiment.

As illustrated in FIG. 12, in a silicon carbide semiconductor device 200 according to the second embodiment, the electric field relaxation region 16 includes a sixth region 16X and a seventh region 16Y. The sixth region 16X is provided on a portion of the fourth region 11D. The lower surface of the sixth region 16X and the upper surface of the fourth region 11D are in contact with each other. The seventh region 16Y is provided on the sixth region 16X. The lower surface of the seventh region 16Y and the upper surface of the sixth region 16X are in contact with each other. Additionally, the upper surface of the seventh region 16Y and the lower surface of the first region 11A are in contact with each other. The effective concentration of a p-type impurity in the seventh region 16Y is higher than the effective concentration of a p-type impurity in the sixth region 16X. The effective concentration of the p-type impurity in the sixth region 16X is, for example, 1.0×10¹⁶ cm⁻³ or greater and 4.0×10¹⁸ cm⁻³ or less. The effective concentration of the p-type impurity in the seventh region 16Y is, for example, 1.0×10¹⁷ cm⁻³ or greater and 5.0×10¹⁸ cm⁻³ or less.

The other configurations are the same as those of the first embodiment.

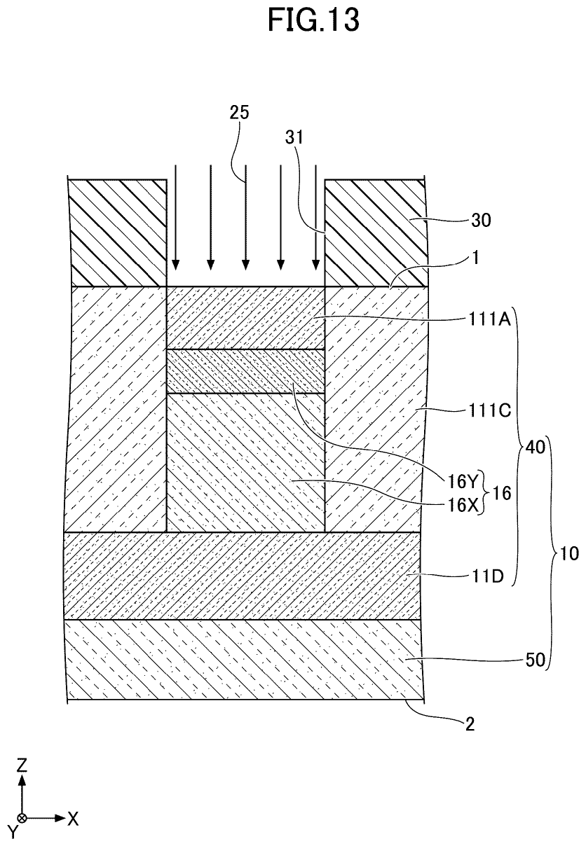

Next, a method of manufacturing the silicon carbide semiconductor device 200 according to the second embodiment will be described. FIG. 13 is a cross-sectional view illustrating the method of manufacturing the silicon carbide semiconductor device according to the second embodiment.

First, the steps up to the ion implantation of the n-type impurity 22 are performed in accordance with the first embodiment (see FIG. 6). In the present embodiment, the electric field relaxation region 16 is not formed when the n-type region 111A is formed. Next, as illustrated in FIG. 13, the seventh region 16Y is formed in the p-type region 116 by performing ion implantation of a p-type impurity 25 through the opening 31. Along with the formation of the seventh region 16Y, the sixth region 16X is formed from the p-type region 116. As a result, the electric field relaxation region 16 including the sixth region 16X and the seventh region 16Y is formed. In the ion implantation of the p-type impurity 25, the ion implantation is performed along the Z-axis and perpendicular to the first main surface 1.

Subsequently, the steps as of the removal of the resist mask 30 are performed in accordance with the first embodiment. In such a way, the silicon carbide semiconductor device 200 according to the second embodiment can be manufactured.

The same effects as the first embodiment can be also obtained by the second embodiment.

### Third Embodiment

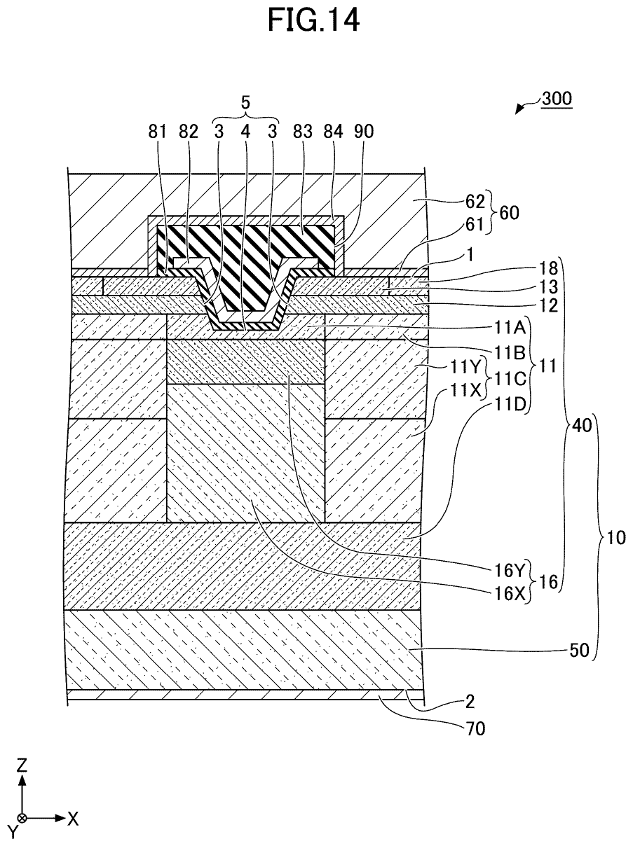

A third embodiment will be described. The third embodiment is different from the second embodiment mainly in the configuration of the third region 11C. FIG. 14 is a cross-sectional view illustrating a silicon carbide semiconductor device according to the third embodiment.

As illustrated in FIG. 14, in a silicon carbide semiconductor device 300 according to the third embodiment, the third region 11C includes an eighth region 11X and a ninth region 11Y. The eighth region 11X is provided on a portion of the fourth region 11D. The lower surface of the eighth region 11X and the upper surface of the fourth region 11D are in contact with each other. The ninth region 11Y is provided on the eighth region 11X. The lower surface of the ninth region 11Y and the upper surface of the eighth region 11X are in contact with each other. Additionally, the upper surface of the ninth region 11Y and the lower surface of the second region 11B are in contact with each other. The effective concentration of an n-type impurity in the ninth region 11Y is higher than the effective concentration of a p-type impurity in the eighth region 11X. The effective concentration of the n-type impurity in the eighth region 11X is, for example, 5.0×10¹⁵ cm⁻³ or greater and 5.0×10¹⁷ cm⁻³ or less. The effective concentration of the n-type impurity in the ninth region 11Y is, for example, 1.0×10¹⁶ cm⁻³ or greater and 1.0×10¹⁸ cm⁻³ or less.

The other configurations are the same as those of the second embodiment.

Here, the interface between the eighth region 11X and the ninth region 11Y may match with the second virtual surface 52 (see FIG. 1), may be closer to the first main surface 1 than the second virtual surface 52 is, or may be closer to the second main surface 2 than the second virtual surface 52 is. As described above, the second virtual surface 52 is a surface that is 1 μm apart from the third surface 43 that is in contact with the second region 11B toward the second main surface 2.

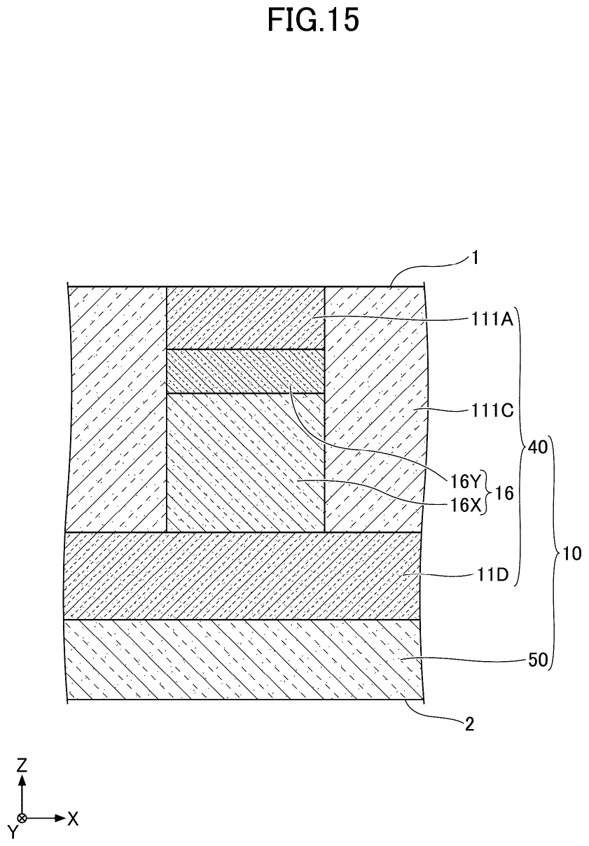

Next, a method of manufacturing the silicon carbide semiconductor device 300 according to the third embodiment will be described. FIG. 15 is a cross-sectional view illustrating the method of manufacturing the silicon carbide semiconductor device according to the third embodiment.

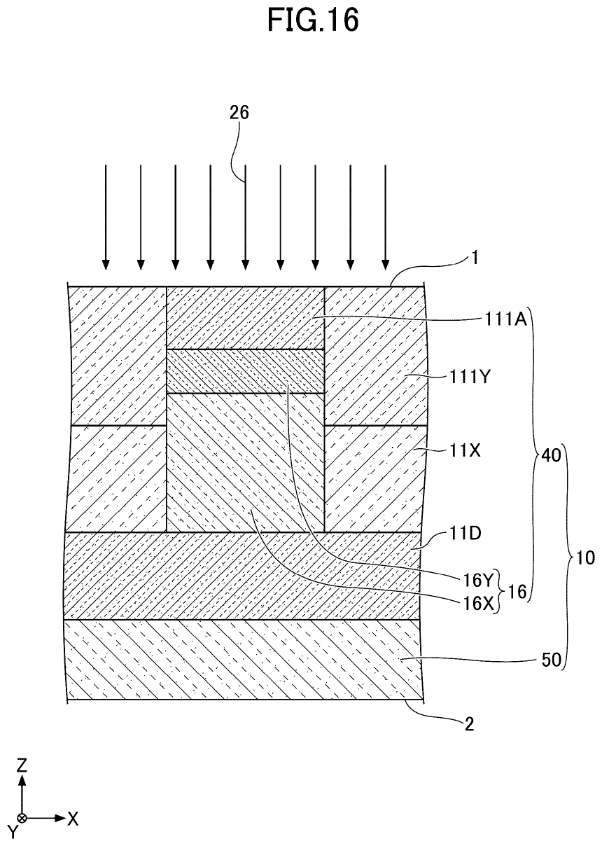

First, as illustrated in FIG. 15, the steps up to the removal of the resist mask 30 are performed in accordance with the second embodiment. Next, as illustrated in FIG. 16, an n-type region 111Y is formed in the n-type region 1110 by performing ion implantation of an n-type impurity 26 on the entire first main surface 1. The n-type region 111Y is a region to be the ninth region 11Y, and is formed to a region shallower than the ninth region 11Y. For example, the n-type region 111Y forms the first main surface 1. Along with the formation of the n-type region 111Y, the eighth region 11X is formed from the n-type region 111C. In the ion implantation of the n-type impurity 26, for example, channeling implantation is performed. That is, the ion implantation is performed perpendicular to the {0001} plane.

Subsequently, the steps as of the formation of the p-type region 112 are performed in accordance with the first embodiment. The second region 11B is formed by performing the ion implantation of the n-type impurity 24 on the entire first main surface 1 (see FIG. 8), and the ninth region 11Y is formed from the n-type region 111x along with the formation of the second region 11B (see FIG. 14). As a result, the third region 11C including the eighth region 11X and the ninth region 11Y is formed. In such a way, the silicon carbide semiconductor device 300 according to the third embodiment can be manufactured.

The same effects as the first and second embodiments can be also obtained by third embodiment.

Here, as a mask used for the ion implantation, a hard mask of polysilicon, silicon oxide, or the like may be used instead of the resist mask.

Although the embodiments have been described in detail above, the present invention is not limited to the specific embodiments, and various modifications and changes can be made within the scope described in the claims.

### DESCRIPTION OF REFERENCE SYMBOLS

1 first main surface

2 second main surface
3 side surface
4 bottom surface
5 gate trench
10 silicon carbide substrate
11 drift region
11A first region
11B second region
11C third region
11D fourth region
11E fifth region
11X eighth region
11Y ninth region
12 body region
13 source region
16 electric field relaxation region
16X sixth region
16Y seventh region
21, 23, 25 p-type impurity
22, 24, 26 n-type impurity
30 resist mask
31 opening
40 silicon carbide epitaxial layer
41 first surface
42 second surface
43 third surface
50 silicon carbide single-crystal substrate
51 first virtual surface
52 second virtual surface
60 source electrode
61 contact electrode
62 source interconnect
70 drain electrode
81 gate insulating film
82 gate electrode
83 interlayer insulating film
84 barrier metal film
90 contact hole
100, 200, 300 silicon carbide semiconductor device
111A 111C 111X 111Y n-type region
112, 116 p-type region
113 n-type region

1. A silicon carbide semiconductor device comprising a silicon carbide substrate having a first main surface and a second main surface opposite to the first main surface,
wherein the silicon carbide substrate includes:
a drift region being of a first conductivity type;
a body region provided on the drift region, the body region being of a second conductivity type different from the first conductivity type; and
a source region provided on the body region so as to be separated from the drift region, the source region being of the first conductivity type,
wherein a gate trench defined by a side surface and a bottom surface is provided in the first main surface, the side surface penetrating the source region and the body region to reach the drift region, and the bottom surface being continuous with the side surface,
wherein the silicon carbide substrate further includes an electric field relaxation region provided between the gate trench and the second main surface, the electric field relaxation region being of the second conductivity type,
wherein the drift region includes:
a first region located between the electric field relaxation region and the first main surface;
a second region adjacent to the first region in a plane parallel to the first main surface;
a third region located between the second region and the second main surface, connected to the second region, and adjacent to the electric field relaxation region in a plane parallel to the first main surface; and
a fourth region located between the electric field relaxation region and the third region; and the second main surface, and connected to the third region;
wherein a first maximum value of an effective concentration of an impurity of the first conductivity type in the first region is greater than a second maximum value of an effective concentration of the impurity of the first conductivity type in the second region,
wherein a third maximum value of an effective concentration of the impurity of the first conductivity type in the third region is less than or equal to the second maximum value, and
wherein a fourth maximum value of an effective concentration of the impurity of the first conductivity type in the fourth region is less than or equal to the third maximum value.

2. The silicon carbide semiconductor device as claimed in claim 1, wherein the third maximum value is greater than the fourth maximum value and less than the second maximum value.

3. The silicon carbide semiconductor device as claimed in claim 1,
wherein the electric field relaxation region has:
a first surface that is in contact with the first region; and
a second surface opposite to the first surface;
wherein an effective concentration of an impurity of the second conductivity type in the electric field relaxation region gradually decreases from a first virtual plane toward the second surface, the first virtual plane being apart from the first surface by 0.3 μm toward the second surface.

4. The silicon carbide semiconductor device as claimed in claim 1, wherein the first maximum value is 50% or greater of a fifth maximum value of an effective concentration of an impurity of the second conductivity type in the electric field relaxation region.

5. The silicon carbide semiconductor device as claimed in claim 1, wherein the second maximum value is 20% or greater of a fifth maximum value of an effective concentration of an impurity of the second conductivity type in the electric field relaxation region.

6. The silicon carbide semiconductor device as claimed in claim 1,
wherein a thickness of the electric field relaxation region is 1 μm or greater,
wherein the electric field relaxation region has a first surface that is in contact with the first region,
wherein the third region has:
a third surface that is in contact with the second region and is flush with the first surface; and
a fifth region between the third surface and a second virtual plane apart from the third surface by 1 μm toward the second main surface; and
wherein an effective concentration of the impurity of the first conductivity type in the fifth region at a position apart from the third surface by a first distance toward the second main surface is 10% or greater of an effective concentration of an impurity of the second conductivity type in the electric field relaxation region at a position apart from the first surface by the first distance toward the second main surface.

7. The silicon carbide semiconductor device as claimed in claim 1, wherein the bottom surface of the gate trench is formed by the first region.

8. The silicon carbide semiconductor device as claimed in claim 1, wherein a width of the first region is greater than a width of the electric field relaxation region.

9. The silicon carbide semiconductor device as claim 1, wherein the side surface of the gate trench includes a {0-33-8} plane.
